(19) United States
(12) Patent Application Publication
(10) Pub. No.: US 2024/0431162 A1
(43) Pub. Date: Dec. 26, 2024

(54) DISPLAY DEVICE AND MANUFACTURING METHOD THEREOF

(71) Applicant: Samsung Display Co., Ltd., Yongin-Si (KR)

(72) Inventors: Deok-Young CHOI, Yongin-si (KR); Won Jang KI, Yongin-si (KR); YEONJU SEO, Yongin-si (KR); JOOHYE JUNG, Yongin-si (KR)

(21) Appl. No.: 18/443,307

(22) Filed: Feb. 16, 2024

(30) Foreign Application Priority Data
Jun. 20, 2023 (KR) 10-2023-0079255

(51) Int. Cl. H10K 59/131; G06F 3/044; H10K 59/12; H10K 59/40; H10K 59/80; H10K 71/60

(52) U.S. Cl. CPC H10K 59/131; G06F 3/0446; H10K 59/1201; H10K 59/40; H10K 59/873; H10K 71/60

(57) ABSTRACT

A display device includes a display area containing multiple pixels, and a pad area outside the display area containing multiple pads. The pads include a first conductive layer on the substrate, a second conductive layer above the first conductive layer, a third conductive layer above the second conductive layer, and a fourth conductive layer above the third conductive layer. The third conductive layer covers the side of the second conductive layer, and the display area includes multiple pixel electrodes, a fifth conductive layer located on the same layer as the third conductive layer, and a first insulating layer located between the fifth conductive layer and the pixel electrodes. No insulating layer is on the same layer as the first insulating layer between the third conductive layer and the fourth conductive layer of the pads, and the side of the third conductive layer has a smooth surface.

### CROSS-REFERENCE TO RELATED APPLICATION

This application claims priority to and the benefit of Korean Patent Application No. 10-2023-0079255 filed at the Korean Intellectual Property Office on Jun. 20, 2023, the entire contents of which are incorporated herein by reference.

### BACKGROUND

### (a) Technical Field

The present disclosure relates to a display device and a manufacturing method thereof.

### (b) Description of the Related Art

A display device such as a liquid crystal display (LCD) or an organic light emitting diode display (OLED display) may include a display panel containing signal lines and pixels capable of displaying images. Each pixel generally includes a pixel electrode to which a data signal is applied, and the pixel electrode is connected to at least one transistor to receive the data signal. The display panel may have a display area that is an area capable of displaying an image and a peripheral area around the display area. A pad area containing a plurality of pads to which a printed circuit film, a driving chip, etc. can be attached may be formed in the peripheral area.

### SUMMARY

Embodiments are intended to prevent the occurrence of defects in or around a pad of a display device during and after manufacturing the display device and to prevent peeling of stacked layers around the pad.

A display device according to an embodiment includes a display area including a plurality of pixels, and a pad area outside the display area and including a plurality of pads, wherein the pads include a first conductive layer on a substrate; a second conductive layer over the first conductive layer, a third conductive layer over the second conductive layer, and a fourth conductive layer over the third conductive layer, the third conductive layer comprising the first conductive layer; covering side surfaces of two conductive layers, and the display area includes a plurality of pixel electrodes, a fifth conductive layer at the same layer as the third conductive layer on the substrate and between the fifth conductive layer and the pixel electrode. It includes a first insulating layer, and there is no insulating layer at the same layer as the first insulating layer between the third conductive layer and the fourth conductive layer of the pad, and the side surface of the third conductive layer has a smooth surface.

It further includes at least one insulating layer between the first conductive layer and the second conductive layer, wherein the at least one insulating layer includes a first opening over the first conductive layer, and the second conductive layer may be electrically connected to the first conductive layer through the first opening.

A side surface of the third conductive layer may contact an uppermost surface of the at least one insulating layer.

It further includes an encapsulation layer on the pixel electrode, and a second insulating layer on the encapsulation layer, wherein the encapsulation layer includes at least one inorganic film and at least one organic film, and the second insulating layer comprising the pad area may include a portion contacting the upper and side surfaces of the third conductive layer.

The second insulating layer may further include a portion between the two adjacent pads and contacting the uppermost surface of the at least one insulating layer.

The display area may further include a plurality of sensing electrodes on the pixel electrode, and the fourth conductive layer of the pad may be at the same layer as the sensing electrode and include the same material.

It further includes a third insulating layer between the second insulating layer and the fourth conductive layer, wherein the fourth conductive layer is in contact with an upper surface of the third insulating layer, and the second insulating layer and the third insulating layer are in contact with each other. The insulating layer may include a second opening on the pad.

A method of manufacturing a display device according to an embodiment includes forming a first conductive layer in a display area and a pad area of a substrate, and a second conductive layer in the display area and the pad area on the first conductive layer, forming a layer, forming a third conductive layer on the second conductive layer and in the display area and the pad area, forming a first insulating layer in the display area and the pad area on the third conductive layer, forming a layer, forming a plurality of pixel electrodes in the display area on the first insulating layer, and forming a protective pattern on the third conductive layer after forming the plurality of pixel electrodes, and removing the first insulating layer in the pad area using the protective pattern as a mask, wherein the first insulating layer includes an organic insulating material and is in the pad area before being removed, and the first insulating layer covers a side surface of the third conductive layer in the pad area.

The first conductive layer, the second conductive layer, and the third conductive layer, which are sequentially stacked on the substrate and in the pad area, are electrically connected to each other to form a pad, and there may be an area where the first insulating layer does not exist between the adjacent pads.

After removing the first insulating layer on the pad area, removing the protective pattern, and forming a fourth conductive layer in the display area and the pad area on the third conductive layer, the fourth conductive layer in the pad area may be electrically connected to the third conductive layer in the pad area and included in the pad.

Forming at least one insulating layer on the display area and the pad area after forming the first conductive layer and before forming the second conductive layer, wherein the at least one insulating layer in the pad area may include a first opening on the first conductive layer, and the second conductive layer of the pad area may be electrically connected to the first conductive layer of the pad area through the first opening.

A side surface of the third conductive layer may contact the uppermost surface of the at least one insulating layer.

The method may further comprise forming an encapsulation layer including at least one inorganic film and at least one organic film on the pixel electrode and forming a second insulating layer on the encapsulation layer, wherein the second insulating layer contacting the upper and side surfaces of the third conductive layer in the pad area may be included.

The second insulating layer may be between the adjacent third conductive layers in the pad area and may further include a part in contact with the top surface of at least one of the insulating layers.

The fourth conductive layer may be formed after forming the encapsulation layer, and the fourth conductive layer in the display area may include a plurality of sensing electrodes.

After forming the second insulating layer and before forming the fourth conductive layer, the method further comprises forming a third insulating layer in the display area and the pad area, wherein the fourth conductive layer is formed. The layer may contact an upper surface of the third insulating layer, and the second insulating layer and the third insulating layer may include a second opening on the pad.

The display area includes a sensing area, and the removal of the first insulating layer includes removing the first insulating layer around the sensing area and removing the substrate in the sensing area.

After forming the plurality of pixel electrodes, further comprising forming a fourth insulating layer over the pixel electrodes, wherein the fourth insulating layer has an opening over the pixel electrodes and forms the protective pattern. The forming step may take place after forming the fourth insulating layer.

The protective pattern may include a metal oxide including IGZO.

The method may further include removing the protective pattern after removing the first insulating layer.

According to the embodiments, it is possible to prevent defects that may occur around a pad or around a pad during and after manufacturing a display device, and to prevent peeling of stacked layers around the pad, thereby preventing short-circuit defects and corrosion between pads.

### BRIEF DESCRIPTION OF THE DRAWINGS

FIG. 1 is a plan view of a display panel included in a display device according to an embodiment.

FIG. 2 is a plan view of a sensing unit of a display device according to an embodiment.

FIG. 3 is a cross-sectional view of a display device according to an embodiment.

FIG. 4 is a cross-sectional view of a sensing area and its surroundings of a display device according to an embodiment.

FIG. 5 is a top plan view of a portion of a pad area of a display device according to an embodiment,

FIG. 6 is a cross-sectional view taken along a cutting plane line AA-BB in an embodiment of the pad area shown in FIG. 5.

FIG. 7 is a cross-sectional view taken along the cutting plane line AA-BB in an embodiment of the pad area shown in FIG. 5.

FIG. 8 is a cross-sectional view of one pad of a display device according to an embodiment.

FIG. 9, FIG. 10, FIG. 11, FIG. 12 and FIG. 13 are cross-sectional views of a pad area of a display device in a sequential manufacturing process according to a method for manufacturing the display device according to an embodiment.

FIG. 14 is a cross-sectional view around a sensing region of a display device in a manufacturing process according to an embodiment.

FIG. 15 is a cross-sectional view around a sensing region of a display device in a manufacturing process after the manufacturing process of FIG. 14.

FIG. 16 shows a cross-section of a pad of a display device according to an embodiment.

FIG. 17 shows a cross-section of a pad and its surroundings for a display device according to a comparative example.

FIG. 18 is a plan view of a pad area of a display device according to a comparative example.

FIG. 19 is a cross-sectional view of a pad area of a display device according to a comparative example.

FIG. 20 shows a cross-section of a pad area of a display device according to a comparative example.

FIG. 21 is a plan view of a pad area of a display device according to a comparative example.

### DETAILED DESCRIPTION OF THE EMBODIMENTS

Hereinafter, various embodiments will be described in detail with reference to the accompanying drawings so that those skilled in the art can make and use the described embodiments. Principles of this disclosure may be embodied in many different forms and are not limited to the embodiments set forth herein.

In order to clearly describe the present invention, parts irrelevant to the description may be omitted, and the same reference numerals are assigned to the same or similar components throughout the specification.

In addition, since the size, shape, and thickness of each component in the drawings may be shown for convenience of explanation, the present disclosure is not necessarily limited to that which is shown.

In the drawings, the thicknesses may be enlarged to clearly express the various layers and regions. In particular, for convenience of explanation, the thicknesses of some layers and regions may be exaggerated.

When a part such as a layer, film, region, or plate is said to be “above” or “on” another part, this includes not only the case where it is “directly on” the other part but also the case where another part exists in the middle thereof. Conversely, when a part is said to be “directly on” another part, it means that there is no other part in between. In addition, being “above” or “on” a reference part means being located above or below the reference part and does not necessarily mean being located “above” or “on” it in the opposite direction of gravity.

In addition, throughout the specification, when a certain component is said to “include,” it means that it may further include other components without excluding other components unless otherwise stated.

Also, throughout the specification, reference made to a “planar image” means that the target part is viewed from above, and reference made to a “cross-sectional image” means a target part cut and the resulting cut face is viewed.

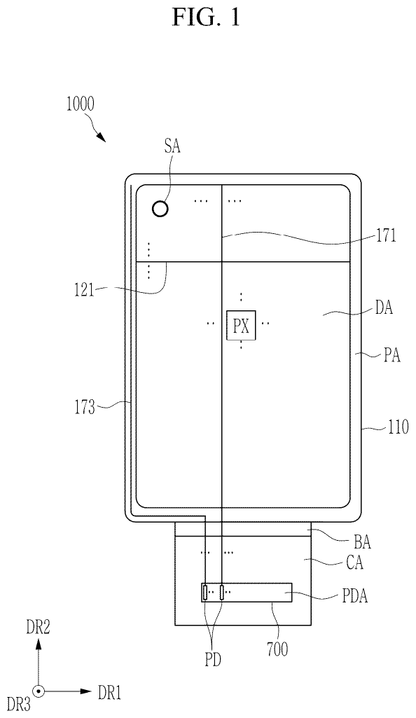

A display device according to an embodiment will be described with reference to FIG. 1 to FIG. 4.

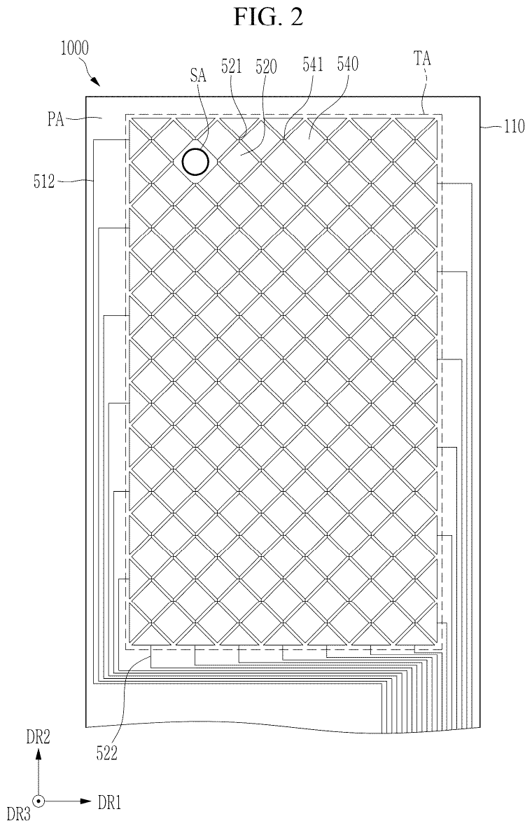

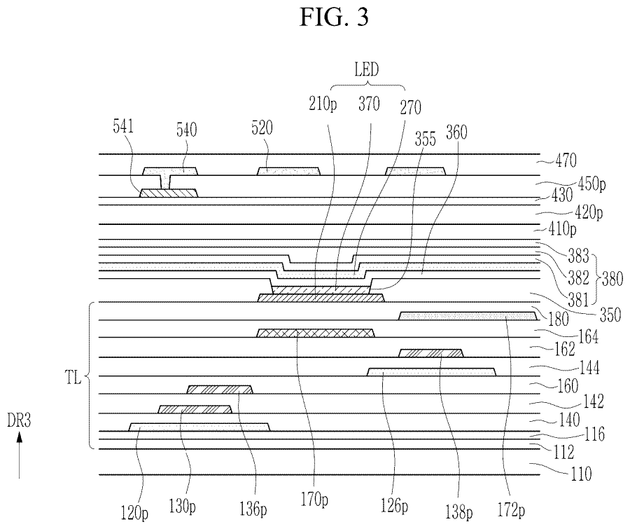

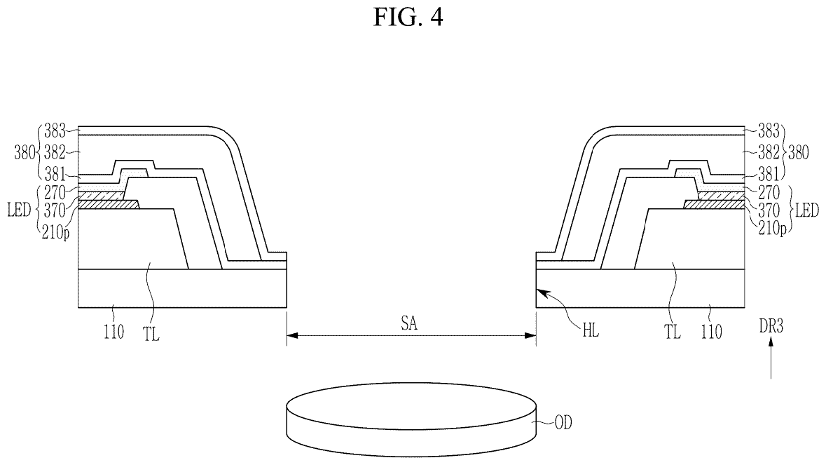

FIG. 1 is a top plan view of a display panel that may be included in a display device according to an embodiment, FIG. 2 is a plan view of a sensing unit of the display device according to an embodiment, and FIG. 3 is cross-sectional view of a display area of the display device according to an embodiment. FIG. 4 shows a cross-sectional view of a sensing area and surroundings of a display device according to an embodiment.

FIG. 1 shows a display panel 1000 for a display device according to an embodiment. The display panel 1000 has a display area DA, which is an area capable of displaying an image, and a non-display area, which is an area other than the display area DA. The display area DA may display an image on a plane parallel to the first and second directions DR1 and DR2. The display area DA includes a plurality of signal lines and a plurality of pixels PX that operates as a unit for displaying an image.

The display panel 1000 includes a substrate 110. Each pixel PX may include at least one transistor formed on the substrate 110 and a pixel electrode connected thereto. For example, when each pixel PX includes at least one light emitting device, each pixel PX may include at least one transistor connected to the light emitting device. In order to implement color display, each pixel PX may display one among several specific colors, and an image of a desired color can be recognized as the sum of images displayed by these specific colors.

The signal lines may include a plurality of scan lines 121 for transmitting scan signals and a plurality of data lines 171 for transmitting data signals. Each scan line 121 mainly extends in the first direction DR1 in the display area DA, and each data line 171 mainly extends in the second direction DR2 in the display area DA. The scan lines 121 and the data lines 171 also extend into the non-display area, where they can be connected to a driving unit 700.

The non-display area may include a peripheral area PA located around the display area DA and a circuit area CA.

The peripheral area PA may be an area adjacent to the display area DA and surrounding the display area DA. At least one signal line 173 may be located in the peripheral area PA. The signal line 173 may extend along the edge of the display area DA and extend to the circuit area CA.

The circuit area CA may be positioned below the lower side of the display area DA. The circuit area CA may include a pad area PDA including a plurality of pads PD and a circuit, which may include at least one transistor.

A driving unit 700 may be mounted on the pad area PDA and be electrically connected to the pad PD. The driving unit 700 may be connected to the display panel 1000 to apply various driving signals and driving voltages to the display panel 1000. The driving unit 700 may be in the form of a flexible printed circuit film, a printed circuit board, or at least one driving circuit chip. FIG. 1 shows an example in which the driving unit 700 is in the form of a driving circuit chip. The plurality of data lines 171 may be connected to the driving unit 700 to receive data signals.

The display panel 1000 included in the display device according to an embodiment may further include a bending area BA. The bending area BA may be located between the circuit area CA and the display area DA and may extend across the substrate 110 in the first direction DR1. The display panel 1000 may be bent at the bending area BA so that the circuit area CA positioned outside the bending area BA may be folded behind the display area DA of the display panel 1000. FIG. 1 illustrates a state in which the display panel 1000 is not bent or folded in the bending area BA. The bending area BA may be omitted depending on the structure of the display device.

Referring to FIG. 2, the display panel 1000 may further include a sensing area TA in which a plurality of sensing electrodes 520 and 540 are formed above the display area DA. An area around the sensing area TA may correspond to the previously described peripheral area PA. Depending on the embodiment, the sensing area TA may include the display area DA of FIG. 1 or may further include a part of the peripheral area PA.

The plurality of sensing electrodes 520 and 540 may include a plurality of first sensing electrodes 520 and a plurality of second sensing electrodes 540. In the sensing area TA, the first sensing electrode 520 and the second sensing electrode 540 are electrically separated from each other. Depending on embodiments, each first sensing electrode 520 may be an input electrode receiving a sensing input signal, and each second sensing electrode 540 may be an output electrode outputting a sensing output signal, or vice versa.

The first sensing electrodes 520 and the second sensing electrodes 540 may be distributed and disposed so as not to overlap each other in the sensing area TA. The first sensing electrode 520 and the second sensing electrode 540 may be positioned at the same layer on the substrate 110 but alternatively may be positioned on different layers.

The first sensing electrode 520 and the second sensing electrode 540 may be formed of a transparent conductor or an opaque conductor, and each of the sensing electrodes 520 and 540 may have a plurality of openings.

The first sensing electrodes 520 may be electrically connected to each other through the first connection part 521, and the plurality of second sensing electrodes 540 may be electrically connected to each other through the second connection part 541. When the first sensing electrodes 520 are connected to each other in one direction, the second sensing electrodes 540 may be connected to each other in another direction crossing the connected first sensing electrodes 520.

When the first sensing electrodes 520 and the second sensing electrodes 540 are positioned at the same layer on the substrate 110, one of the first connection part 521 and the second connection part 541 may be in the same layer as the first sensing electrode 520 and the second sensing electrode 540, and the other connection part may be positioned on a different layer from the first sensing electrode 520 and the second sensing electrode 540.

A plurality of sensing wires 512 and 522 connected to the plurality of first sensing electrodes 520 and the plurality of second sensing electrodes 540, respectively, are formed in the peripheral area of the sensing area TA. Each first sensing wire 512 can be connected to a plurality of second sensing electrodes 540 arranged in a first direction DR1—for example, and each second sensing wire 522 can be connected to a plurality of first sensing electrodes 520 arranged in a second direction DR2. Depending on the embodiment, the first sensing wires 512 and the second sensing wires 522 may be electrically connected to some of the pads PD of the pad area PDA of FIG. 1.

FIG. 2 illustrates a mutual-cap type sensing unit that senses a touch using two sensing electrodes 520 and 540. However, depending on the embodiment, the sensing unit may be formed as a self-cap type sensing unit that senses a touch using only one sensing electrode.

Referring to FIG. 1, FIG. 2, and FIG. 4, a display area DA according to an embodiment may include a sensing area SA and may further include at least one optical device OD positioned below the display panel 1000. The sensing area SA may be an area through which light is incident to or emitted from the optical device OD positioned (in the third direction DR3) below the display panel 1000. The sensing area SA may have higher light transmittance than the surrounding display area DA and the peripheral area PA.

The optical device OD may include a camera, a flash, a sensor, and the like. For example, the optical device OD may emit light in a certain wavelength range toward an object positioned on or near the display panel 1000, or receive light reflected from the object. Such light of a certain wavelength may either be light of a wavelength other than the visible light spectrum, which is the light of the image displayed in the display area DA and can be processed in the optical device OD, or may be light in the visible light spectrum, like the light of the image displayed in the display area DA.

The optical device OD overlaps the sensing area SA in the third direction DR3, and the light emitted from or incident to the optical device OD may be emitted from the sensing area SA of the display panel 1000. In a plan view, the optical device OD may have an area corresponding to the whole or part of the sensing area SA. As shown in FIG. 1, the sensing area SA may be located close to the upper end of the display area DA and may be located approximately at the center of the display area DA in the first direction DR1, but the location of the sensing area SA is not limited thereto.

Referring to FIG. 4, the substrate 110 included in the display panel 1000 may have an opening HL, which may be formed by removing a portion of the substrate 110 corresponding to (or overlapping) the sensing area SA. The optical device OD may be disposed to correspond to the opening HL of the substrate 110.

A cross-sectional structure of a display device according to an embodiment will be described with reference to FIG. 3 and FIG. 4 along with FIG. 1 and FIG. 2.

Referring to FIG. 3, a display device according to an embodiment includes a substrate 110, and sequentially on the substrate 110 further includes a barrier layer 112, a buffer layer 116, a first semiconductor layer 120p, an insulating layer 140, first conductive layer 130p, a second insulating layer 142, a second conductive layer 136p, a third insulating layer 160, a second semiconductor layer 126p, a fourth insulating layer 144, a third conductive layer 138p, a fifth insulating layer 162, a fourth conductive layer 170p, a sixth insulating layer 164, a fifth conductive layer 172p, a seventh insulating layer 180, a pixel electrode 210p, an eighth insulating layer 350, a light emitting layer 370, a common layer 360, a common electrode 270, an encapsulation layer 380, a ninth insulating layer 410p, a tenth insulating layer 420p, an eleventh insulating layer 430, a second connection part 541 of the first sensing conductive layer, a twelfth insulating layer 450p, a second sensing electrode 540 of the second sensing conductive layer, a first sensing electrode 520 and a thirteenth insulating layer 470.

The substrate 110 may include a rigid material, such as glass, that does not bend or may include a flexible material that can bend, such as plastic or polyimide.

The barrier layer 112 and the buffer layer 116 may include an organic insulating material or an inorganic insulating material such as silicon oxide (SiOₓ), silicon nitride (SiNx), and silicon nitride oxide (SiOₓN_{y}). At least one of the barrier layer 112 and the buffer layer 116 may be omitted in some embodiments.

The first semiconductor layer 120p may include an oxide semiconductor, amorphous silicon, or polycrystalline silicon, which may be patterned and include an active or channel region between conductive semiconductor regions. The first conductive layer 130p may be patterned to include a first gate electrode overlapping the channel region of the first semiconductor layer 120p. The first gate electrode and an underlying region of the first semiconductor layer 120p may together form a first transistor.

The first conductive layer 130p may include a metal such as copper (Cu), molybdenum (Mo), aluminum (Al), silver (Ag), chromium (Cr), tantalum (Ta), or titanium (Ti) or include a metal alloy of such metals. The first conductive layer 130P may be made of a single layer or multiple layers.

The second conductive layer 136p may overlap at least a portion of the first conductive layer 130p to form a capacitor. The second conductive layer 136p may receive a driving voltage.

The second semiconductor layer 126p may include an oxide semiconductor, amorphous silicon, or polycrystalline silicon, which may be patterned and include an active or channel region between conductive semiconductor regions. Depending on the embodiment, the semiconductor material of the second semiconductor layer 126p and the semiconductor material of the first semiconductor layer 120p may be different from each other. For example, the first semiconductor layer 120p may include polycrystalline silicon, and the second semiconductor layer 126p may include an oxide semiconductor.

The third conductive layer 138p may include a second gate electrode overlapping the channel region of the second semiconductor layer 126p. The second gate electrode and the second semiconductor layer 126p may together form a second transistor. The third conductive layer 138p may include a metal such as copper (Cu), molybdenum (Mo), aluminum (Al), silver (Ag), chromium (Cr), tantalum (Ta), or titanium (Ti) or include a metal alloy of such metals. The third conduction layer 138P may be made of a single layer or multiple layers.

The fourth conductive layer 170p may include a plurality of connection electrodes. For example, the fourth conductive layer 170p may include a connection electrode electrically connecting a conductive region of the first semiconductor layer 120p and a conductive region of the second semiconductor layer 126p. The fourth conductive layer 170p may be formed of a single layer or multiple layers and may include aluminum (Al), platinum (Pt), palladium (Pd), silver (Ag), magnesium (Mg), gold (Au), nickel (Ni), neodymium (Nd), iridium (Ir), chromium (Cr), calcium (Ca), molybdenum (Mo), titanium (Ti), tungsten (W), and/or copper (Cu) etc. For example, the fourth conductive layer 170p may be formed of a triple layer such as Ti/Al/Ti.

At least one of the first insulating layer 140, the second insulating layer 142, the third insulating layer 160, the fourth insulating layer 144, and the fifth insulating layer 162 is made of silicon oxide (SiOₓ) or may include another inorganic insulating material such as silicon nitride (SiNx), silicon oxynitride (SiOₓN_{y}), and the like. Some or all of the insulating layers 140, 142, 160, 144, and 162 may alternatively or additionally include an organic insulating material.

The fifth conductive layer 172p may include a data line or a driving voltage line. The fifth conductive layer 172p may be formed of a single layer or multiple layers and may include aluminum (Al), platinum (Pt), palladium (Pd), silver (Ag), magnesium (Mg), gold (Au), nickel (Ni), neodymium (Nd), iridium (Ir), chromium (Cr), calcium (Ca), molybdenum (Mo), titanium (Ti), tungsten (W), and/or copper (Cu) etc. For example, the fifth conductive layer 172p may be formed of a triple layer such as Ti/Al/Ti.

At least one of the sixth insulating layer 164 and the seventh insulating layer 180 may include a general-purpose polymer such as polymethylmethacrylate (PMMA) or polystyrene (PS), a polymer derivative having a phenolic group, an acrylic polymer, or an imide polymer, The insulating layer 164 or 180 may include an inorganic insulating material or an organic insulating material such as polyimide, an acrylic polymer, or a siloxane-based polymer.

Layers stacked between the pixel electrode 210p and the substrate 110 may be referred to as a pixel circuit layer TL.

The pixel electrode 210p may be made of a transparent conductive material such as indium tin oxide (ITO), poly-ITO, indium zinc oxide (IZO), indium gallium zinc oxide (IGZO), and/or indium tin zinc oxide (ITZO). Alternatively, at least one of several metal materials such as silver (Ag), molybdenum (Mo), copper (Cu), gold (Au), and aluminum (Al) may be included.

The eighth insulating layer 350 may include an organic insulating material such as polyimide, polyamide, acrylic resin, benzocyclobutene, or phenol resin. The eighth insulating layer 350 may include an opening 355 positioned on each pixel electrode 210p.

The emission layer 370 and the common layer 360 may be positioned on the eighth insulating layer 350 and the pixel electrode 210p. The light emitting layer 370 may include a portion positioned within the opening 355 of the eighth insulating layer 350. The light emitting layer 370 may include an organic light emitting material or an inorganic light emitting material. The common layer 360 may include a hole injection layer, a hole transport layer, an electron injection layer, an electron transport layer, and the like, and may be formed not only in the opening 355 of the eighth insulating layer 350 but also on the eighth insulating layer 350. The common layer 360 may include an organic material.

FIG. 3 shows that the common layer 360 may include a portion positioned between the light emitting layer 370 and the pixel electrode 210p. Depending on the embodiment, common layer 360 may only be on the light emitting layer 370 or may extend beyond the light emitting layer 370 onto the eighth insulating layer 350 as shown in FIG. 3. The common layer 370 may include a hole injection layer and a hole transport layer positioned between the light emitting layer 370 and the pixel electrode 210p, and the electron transport layer and the electron injection layer may be positioned between the light emitting layer 370 and the common electrode 270. The common layer 360 may be omitted in some embodiments as shown in FIG. 4.

The common electrode 270 may include a transparent conductive material such as indium tin oxide (ITO), indium zinc oxide (IZO), indium gallium zinc oxide (IGZO), and indium tin zinc oxide (ITZO). The common electrode 270 may have translucent characteristics. As shown in FIG. 4, the common electrode 270 and the pixel electrode 210p may form a light emitting element LED together with the light emitting layer 370 therebetween.

The encapsulation layer 380 may include at least one inorganic layer and at least one organic layer. For example, as shown in FIG. 3 and FIG. 4, the encapsulation layer 380 may include a first inorganic encapsulation layer 381, an organic encapsulation layer 382, and a second inorganic encapsulation layer 383 sequentially stacked. As shown in FIG. 4, the organic encapsulation layer 382 may have an end or an edge spaced apart from the opening HL of the substrate 110, and the first and second inorganic encapsulation layers 381 and 383 enclose the end of the organic encapsulation layer 382. The encapsulation layer 380, particularly the first and second encapsulation layers 381 and 383, may further extend toward the opening HL and have an edge adjacent to the edge of the opening HL in the substrate 110.

The first and second inorganic layers 381 and 383 together with the substrate 110 may define the opening HL, and the opening HL may be formed by removing portions the first and second inorganic layers 381 and 383 and the substrate 110 that are in or that correspond to the sensing area SA. The encapsulation layer 380 may seal around the opening HL to prevent foreign matter such as moisture from penetrating into the display panel 1000 through the opening HL.

At least one of the ninth insulating layer 410p, the eleventh insulating layer 430, and the twelfth insulating layer 450p is an inorganic insulating material such as silicon oxide (SiOₓ), silicon nitride (SiNx), or silicon oxynitride (SiOxNy), or an organic insulating material such as an acrylic resin, a methacrylic resin, polyisoprene, a vinyl resin, an epoxy resin, a urethane resin, a cellulose resin, and a perylene resin may be included.

The tenth insulating layer 420p as shown in FIG. 3 may be a layer for planarization and may include an organic insulating material such as acrylic resin, methacrylic resin, polyisoprene, vinyl resin, epoxy resin, urethane resin, cellulose resin, and perylene resin. The tenth insulating layer 420p may be formed only in a partial area of the display area DA or the sensing area TA.

At least one of the first sensing conductive layer and the second sensing conductive layer may be formed of a single layer or a multi-layer, and may include aluminum (Al), platinum (Pt), palladium (Pd), silver (Ag), magnesium (Mg), Gold (Au), Nickel (Ni), Neodymium (Nd), Iridium (Ir), Chromium (Cr), Calcium (Ca), Molybdenum (Mo), Titanium (Ti), Tungsten (W), and/or copper (Cu). For example, the first or second sensing conductive layer may be formed of a triple layer such as Ti/Al/Ti.

Unlike the example of FIG. 3, the first sensing electrode 520 and the second sensing electrode 540 may be in the first sensing conductive layer along with the first connection part 521, and the second connection part 541 may be in the second sensing conductive layer. In another alternative, the first sensing electrode 520 and the second sensing electrode 540 may be in the first sensing conductive layer together with the second connection part 541, and the first connection part 521 may be in the second sensing conductive layer. In another alternative, the first connection part 521 and the first sensing electrode 520 may be together in one (first or second) sensing conductive layers, and the second connection part 541 and the second sensing electrode 540 may be together in the other (second or first) sensing conductive layer.

The thirteenth insulating layer 470 is a layer for protecting the first sensing conductive layer and the second sensing conductive layer and may include an organic insulating material.

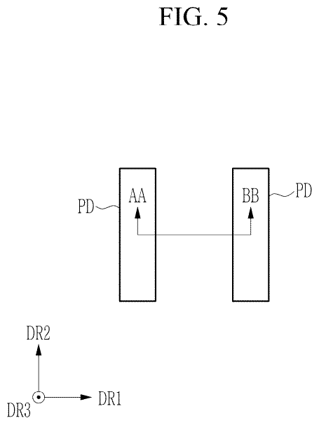

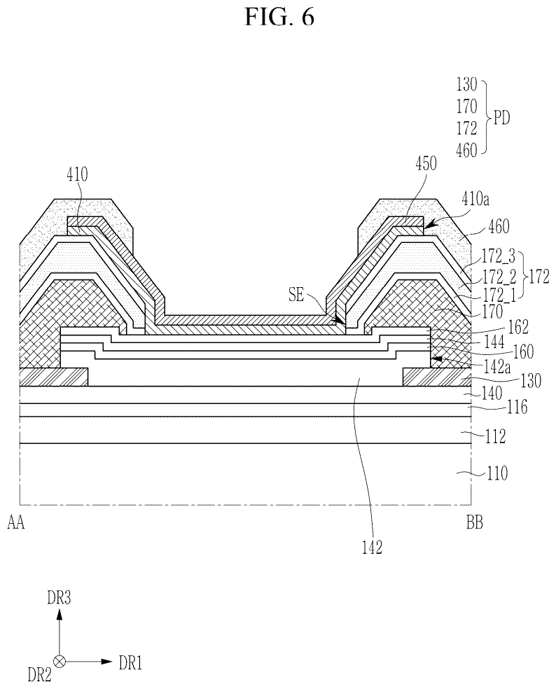

The pad area PDA of the display panel will be described with reference to FIG. 5 to FIG. 8 along with FIG. 1 to FIG. 4 described above. The duplicate description of components identical to those described above may be omitted below. FIG. 5 is a top plan view of a portion of a pad area of a display device according to an embodiment, and FIG. 6 is a cross-sectional view taken along a cut plane line AA-BB in an embodiment of the pad area shown in FIG. 5.

Referring to FIG. 6, a barrier layer 112, a buffer layer 116, and a first insulating layer 140 are sequentially stacked on a substrate 110 of a display panel, and a first conductive layer 130 is positioned thereon. The first conductive layer 130 may be patterned and formed in an area corresponding to the pads PD, and regions of the first conductive layer 130 for adjacent pads PD may be spaced apart from each other as shown in FIG. 6. The first conductive layer 130 of FIG. 6 may be positioned at the same layer as the first conductive layer 130p of the display area DA show in FIG. 3, and the first conductive layers 130 and 130p may include the same material and may be formed together in the same process.

At least one insulating layer may be formed on the first conductive layer 130 and extending between regions of the first conductive layer 130. FIG. 6 shows a second insulating layer 142, a third insulating layer 160, a fourth insulating layer 144, and a fifth insulating layer 162, which may be sequentially stacked on the first conductive layer 130. An example including the insulating layer 162 is shown. At least one insulating layer, which may include the second insulating layer 142, the third insulating layer 160, the fourth insulating layer 144, and the fifth insulating layer 162, is patterned to form an opening 142a above the first conductive layer 130.

A fourth conductive layer 170 may be on the fifth insulating layer 162. The fourth conductive layer 170 may be patterned and formed in an area corresponding to the pads PD. The fourth conductive layer 170 may contact and be electrically connected to the first conductive layer 130 through the opening 142a. The fourth conductive layer 170 may be positioned at the same layer as the fourth conductive layer 170p of the display area DA, may include the same material, and may be formed together in the same process.

A fifth conductive layer 172 may be on the fourth conductive layer 170. The fifth conductive layer 172 may be patterned and formed in an area corresponding to the pads PD. The fifth conductive layer 172 is positioned on the fourth conductive layer 170 and may contact and be electrically connected to the fourth conductive layer 170. The fifth conductive layer 172 may cover the side surface of the fourth conductive layer 170. The fifth conductive layer 172 may be the same layer as the fifth conductive layer 172p of the display area DA, may include the same material, and may be formed together in the same process. Referring to FIG. 6, the fifth conductive layer 172 and the fifth conductive layer 172p of the display area DA show a structure formed of a triple layer such as Ti/Al/Ti, for example. More particularly, the fifth conductive layer 172 may include a lower layer 172_1, a middle layer 172_2, and an upper layer 172_3, and the lower layer 172_1 and the upper layer 172_3 may include titanium (Ti), the middle layer 172_2 may include aluminum (Al).

A side surface SE of the fifth conductive layer 172 overlies the second insulating layer 142, the third insulating layer 160, the fourth insulating layer 144, and the fifth insulating layer 162. The fifth conductive layer 172 may contact the uppermost surface of at least one insulating layer. For example, the side surface SE of the fifth conductive layer 172 may contact the upper surface of the fifth insulating layer 162.

At least one insulating layer may be positioned on the fifth conductive layer 172 and the fifth insulating layer 162. FIG. 6 shows an example in which a ninth insulating layer 410 and the twelfth insulating layer 450 are sequentially stacked on the fifth conductive layer 172 and the fifth insulating layer 162, but at least one of the ninth insulating layer 410 and the twelfth insulating layer 450 overlapping the pad PD may be omitted some embodiments. A region of the ninth insulating layer 410 and the twelfth insulating layer 450 may overlap (in the third direction DR3) portions of edges of two adjacent pads PD, may overlap a region of insulating layer 142 between the two pads PD, and may overlap the pad PD, so most of the area of the fifth conductive layer 172 including the central part is not covered. The region of the ninth insulating layer 410 and the twelfth insulating layer 450 between two adjacent pads PD and overlapping the two adjacent pads PD may be continuously formed. The ninth insulating layer 410 and the twelfth insulating layer 450 may be patterned to include an opening 410a positioned over the fifth conductive layer 172. Referring to FIG. 6, the ninth insulation layer 410 may contact with the top surface and the side surface SE of the fifth conductive layer 172, and it can also touch the top of the fifth insulation layer 162 located between the adjacent pads PD.

The ninth insulating layer 410 is positioned at the same layer as the ninth insulating layer 410p of the display area DA, may include the same material, and may be formed together in the same process. That is, the ninth insulating layer 410 may be a part of the ninth insulating layer 410p in the display area DA.

The twelfth insulating layer 450 is located at the same layer as the twelfth insulating layer 450p of the display area DA, may include the same material, and may be formed together in the same process. That is, the twelfth insulating layer 450 may be a part of the twelfth insulating layer 450p in the display area DA.

A sixth conductive layer 460 may be positioned on the twelfth insulating layer 450 and the fifth conductive layer 172. The sixth conductive layer 460 may be patterned and formed in an area corresponding to the pad PD. The sixth conductive layer 460 is positioned on the fifth conductive layer 172 and may contact and be electrically connected to the fifth conductive layer 172.

The first conductive layer 130, the fourth conductive layer 170, the fifth conductive layer 172, and the sixth conductive layer 460, which are sequentially stacked from the bottom and electrically connected to each other, form one pad PD. Some of the first conductive layer 130, the fourth conductive layer 170, the fifth conductive layer 172, and the sixth conductive layer 460 included in the pad PD may be omitted, and a conductive layer different from the conductive layers corresponding to the area DA and may be formed in a different process. In the illustrated embodiment, the sixth conductive layer 460 may be located at the same layer as the second sensing electrode 540 and the second sensing conductive layer of the first sensing electrode 520 in the display area DA, and the sixth conductive layer 460 may contain the same material and may be formed together in the same process.

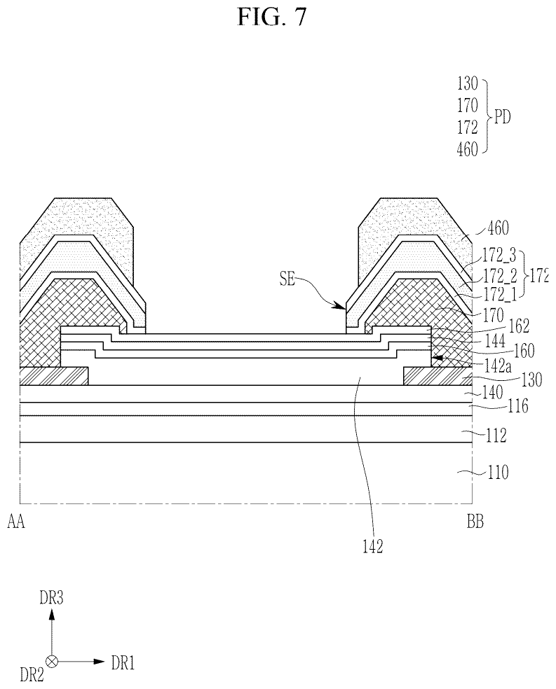

FIG. 7 is a cross-sectional view taken along the cut plane line AA-BB through another embodiment of the pad area shown in FIG. 5. The display device according to the embodiment of FIG. 7 is mostly identical to the embodiment of FIG. 6, but the embodiment of FIG. 7 may not have an insulating layer between the fifth conductive layer 172 and the sixth conductive layer 460 forming the pad PD. That is, the ninth insulating layer 410 and the twelfth insulating layer 450 on the fifth conductive layer 172 and the fifth insulating layer 162 in the embodiment of FIG. 6 may be omitted from the embodiment of FIG. 7.

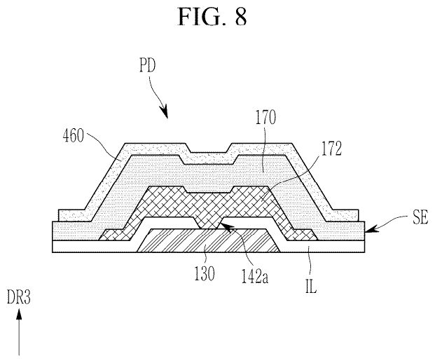

FIG. 8 is a cross-sectional view of one pad PD of a display device according to an embodiment. Referring to FIG. 8, the pad PD includes the first conductive layer 130, the fourth conductive layer 170, the fifth conductive layer 172, and the sixth conductive layer 460, which are among a plurality of patterned conductive layers, such as layer 460, described above. As described above, an insulating layer IL positioned between the first conductive layer 130 and the fourth conductive layer 170 may include at least one insulating layer such as one or more of the second insulating layer 142, the third insulating layer 160, the fourth insulating layer 144 and the fifth insulating layer 162. The insulating layer IL may include the opening 142a for connection between the fourth conductive layer 170 and the first conductive layer 130.

Referring to FIG. 6 to FIG. 8, the side surface SE of the fifth conductive layer 172 of the pad PD according to the embodiment is not lost or damaged during the manufacturing process and may have a substantially smooth or flat surface. In addition, there is no defect in which metal components such as aluminum (Al) of the fifth conductive layer 172 are precipitated around the pad PD and remain in the form of particles.

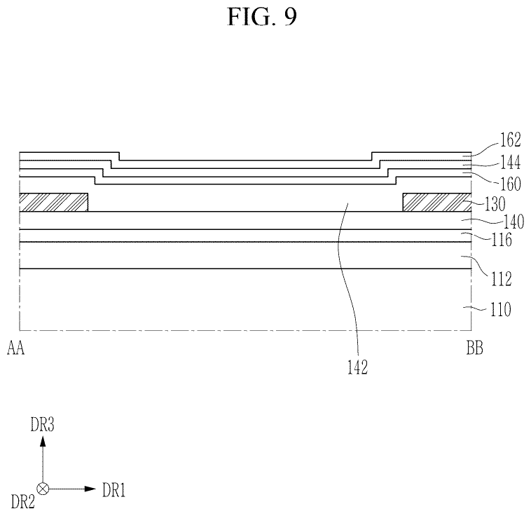

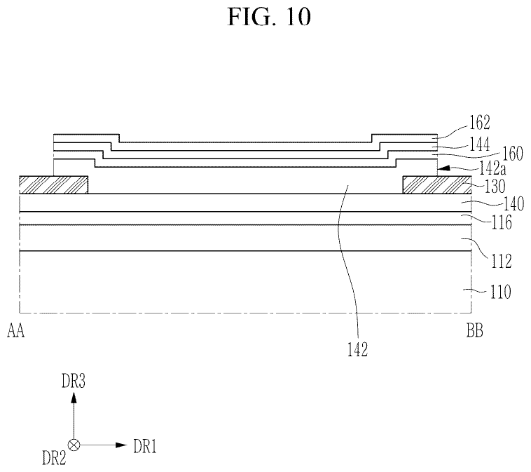

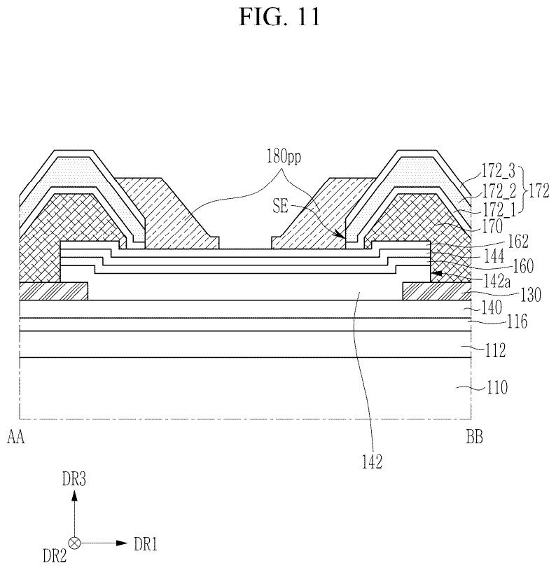

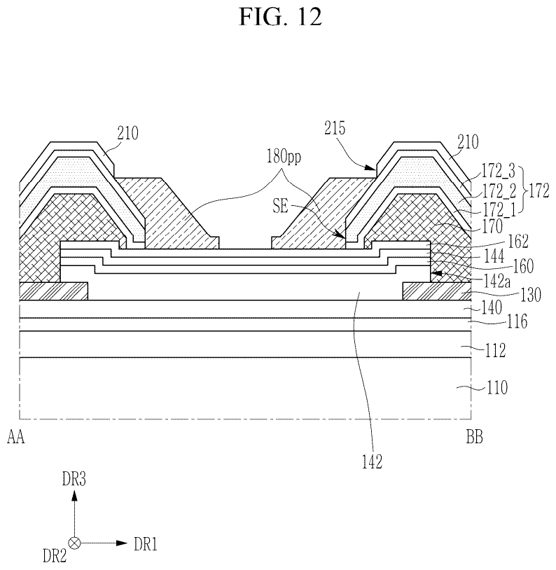

A method of manufacturing a display device according to an embodiment will be described with reference to FIG. 9 to FIG. 14 along with the previously described drawings.

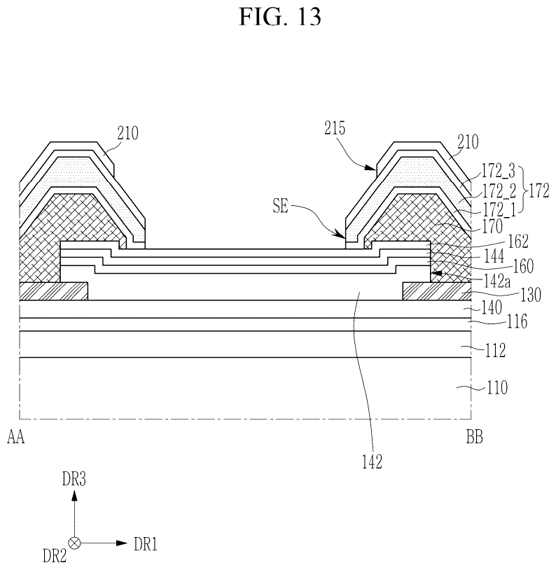

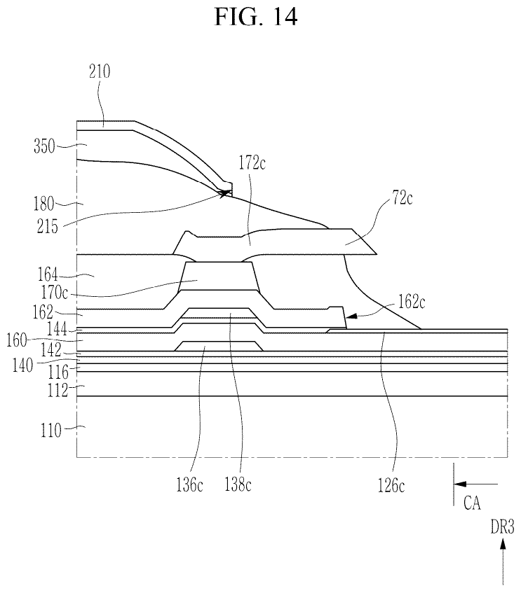

FIG. 9 to FIG. 13 are cross-sectional views of the pad area of the display device during a sequential manufacturing process according to method of manufacturing the display device according to one embodiment, and FIG. 14 is a cross-sectional view around the sensing area of the display device in a manufacturing process according to the manufacturing method of the display device according to one embodiment.

First, referring to the pad area shown in FIG. 9, after sequentially stacking a barrier layer 112, the buffer layer 116, and a first insulating layer 140 on a substrate 110, a conductive material is stacked thereon and patterned to form the first conductive layer 130. Next, at least one insulation layer, which may include the second insulation layer 142, the third insulation layer 160, the fourth insulation layer 144, and the fifth insulation layer 162, is stacked on the first conductive layer 130.

Referring to FIG. 14, while manufacturing the structure of FIG. 9, at least one conductor positioned between the buffer layer 116 and the fifth insulating layer 162 may be further formed on the substrate 110 around the sensing area SA. For example, as shown in FIG. 14, a conductor 136c may be positioned between the second insulating layer 142 and the third insulating layer 160, and a conductor 138c may be positioned between the fourth insulating layer and the fifth insulating layer 162. The conductor 136c may be at the same layer as the second conductive layer 136p of the display area DA, may include the same material as the second conductive layer 136p, and may be formed together with the second conductive layer 136p in the same process. The conductor 138c may be positioned at the same layer as the third conductive layer 138p of the display area DA, may include the same material as the third conductive layer 138p, and may be formed together with the third conductive layer 138p in the same process.

Again, referring to FIG. 14, while manufacturing the structure of FIG. 9, at least one semiconductor layer positioned between the buffer layer 116 and the fifth insulating layer 162 may be formed on the substrate 110 around the sensing area SA. For example, as shown in FIG. 14, a semiconductor layer 126c may be patterned and formed between the third insulating layer 160 and the fourth insulating layer 144. The semiconductor layer 126c may have an edge aligned with an edge of the sensing area SA. The semiconductor layer 126c is located at the same layer as the second semiconductor layer 126p of the display area DA, may include the same material as the second semiconductor layer 126p, and may be formed together with the second semiconductor layer 126p in the same process.

Referring to FIG. 10, at least one insulating layer on the first conductive layer 130 is patterned using a photolithography process to form the openings 142a positioned pad regions on the first conductive layer 130.

Referring to FIG. 14, when the openings 142a are formed, the fourth insulating layer 144 and the fifth insulating layer 162, which are insulating layers positioned on the semiconductor layer 126c, may be patterned to form an opening 162c positioned on the semiconductor layer 126c. In this case, the semiconductor layer 126c may serve as an etch stopper when forming the opening 162c.

Referring to FIG. 11, the fourth conductive layer 170 is formed by stacking and patterning a conductive material on the substrate 110.

Referring to FIG. 14, when forming the fourth conductive layer 170, a conductor 170c positioned on the fifth insulating layer 162 may be further formed on the substrate 110 around the sensing area SA. The conductor 170c may be positioned at the same layer, may include the same material, and may be formed together in the same process as the fourth conductive layer 170p of the display area DA and the fourth conductive layer 170 of the pad area.

Referring to FIG. 11 and FIG. 14, a sixth insulating layer 164 is stacked on the substrate 110 on which the fourth conductive layer 170 and the conductor 170c are formed and then patterned to form the fourth conductive layer 170 of the pad PD. The sixth insulating layer 164 on the fourth conductive layer 170 may be removed. In this case, the sixth insulating layer 164 around the sensing area SA may not be removed.

A conductive material is subsequently deposited and patterned on the substrate 110 to form the fifth conductive layer 172 and the conductor 172c around the sensing area SA. As shown in FIG. 14, the conductor 172c may have a protruding part 72c that protrudes outward more than the conductor 170c. Accordingly, an undercut may be formed below the conductor 172c.

Referring back to FIG. 6, the fifth conductive layer 172 may include the lower layer 172_1, the middle layer 172_2, and the upper layer 172_3, and the lower layer 172_1 and the upper layer 172_3 may include titanium (Ti), and the middle layer 172_2 may include aluminum (Al). The conductor 172c may also have the same stacked structure as the fifth conductive layer 172.

The conductor 136c, the conductor 138c, the conductor 170c, and the conductor 172c positioned around the sensing area SA may overlap each other in the third direction DR3.

Next, a photosensitive organic insulating material or the like is laminated on the fifth conductive layer 172 and the conductor 172c to form the seventh insulating layer 180, and the seventh insulating layer 180 is patterned through a photo process or the like. Thus, an insulating pattern 180pp in the pad area is formed as shown in FIG. 11. The insulating pattern 180pp covers the side surface SE of the fifth conductive layer 172 of each pad PD without overlapping most of the central portion of the fifth conductive layer 172 on a plan view. Adjacent insulating patterns 180pp covering the side surface SE of the fifth conductive layer 172 of the adjacent pad PD may thus be spaced apart from each other. That is, there may be a region where the seventh insulating layer 180 or the insulating pattern 180pp does not exist between the adjacent pads PD.

In particular, when the fifth conductive layer 172 is formed of a triple layer such as Ti/Al/Ti, the middle layer could be exposed from the side surface SE of the fifth conductive layer 172, but in the display according to the present embodiment in the manufacturing method of the device, the side surface SE of the fifth conductive layer 172 may be covered with the insulating pattern 180pp to be protected from an etchant or the like in a subsequent process.

In the photo process for forming the insulating pattern 180pp, a halftone mask may be used to form the insulating pattern 180pp having a thickness smaller than that of the seventh insulating layer 180 located elsewhere on the substrate 110. However, the embodiment is not limited thereto.

Referring to FIG. 14, the seventh insulating layer 180 around the sensing area SA may be patterned to have an edge positioned on the conductor 172c.

Subsequently, a transparent conductive material such as ITO, poly-ITO, IZO, IGZO, ITZO, and/or silver (Ag), molybdenum (Mo), copper (Cu), or gold is formed on the seventh insulating layer 180. A plurality of pixel electrodes are formed by stacking and patterning conductive materials such as (Au) and metal materials such as aluminum (Al). In this process, since the etchant used in patterning the pixel electrodes does not come into contact with the side surface SE of the fifth conductive layer 172 covered with the insulating pattern 180pp and aluminum (Al) of the fifth conductive layer 172, and thus precipitation of these metal components can be prevented. In particular, when the fifth conductive layer 172 is formed of a triple layer, precipitation of a metal component from the side surface of the middle layer 172_2 of the triple layer can be prevented.

Referring to FIG. 14, an eighth insulating layer 350 may be stacked and patterned on the seventh insulating layer 180. In this step, an opening positioned on each pixel electrode of the display area DA may be formed in the eighth insulating layer 350. In addition, the eighth insulating layer 350 around the sensing area SA may be patterned to have an edge positioned on the conductor 172c.

Referring to FIG. 12 and FIG. 14, a protective pattern 210 having an opening 215 exposing the insulating pattern 180pp is formed by stacking and patterning a conductive material on the substrate 110. The opening 215 of the protective pattern 210 may also expose the fifth insulating layer 162 between the adjacent insulating patterns 180pp. Referring to FIG. 14, the protection pattern 210 may have an opening 215 having an edge positioned on the conductor 172c around the sensing area SA. The opening 215 may expose the protruding portion 72c of the protruding portion 72c to the edge of the sensing area SA. The protective pattern 210 may include a metal oxide such as IGZO.

Next, referring to FIG. 13, the insulating pattern 180pp is etched and removed using the protective pattern 210 as an etching mask. In this case, a dry etching process may be used.

Referring to FIG. 14, in this step, organic insulating materials not covered with the protective pattern 210 around the sensing area SA—for example, the sixth insulating layer 164 and the seventh insulating layer 180—are removed. In this case, the semiconductor layer 126c may function as an etch stopper. At this stage, the sixth insulating layer 164 under the protruding part 72c of the conductive body 172c can also be removed, so an undercut can be formed under the protruding part 72c, and the protruding part 72c can protrude in a horizontal direction. Then, the protective pattern 210 is removed.

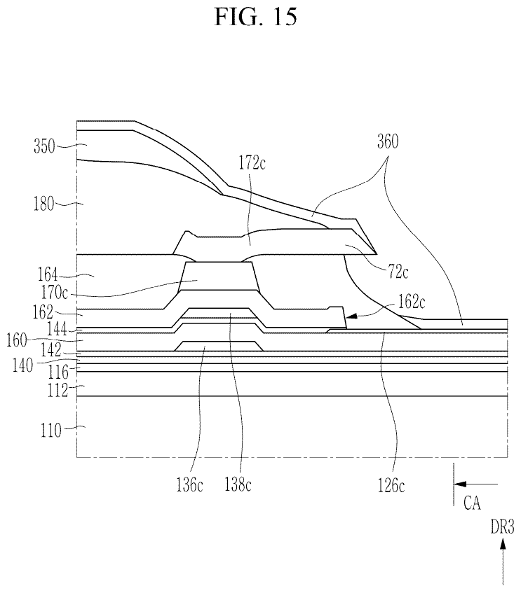

Referring to FIG. 15, the light emitting layer and a common layer 360 may be stacked on the substrate 110 on which the eighth insulating layer 350 was formed. The common layer 360 can be separated by the protrusion 72c forming the undercut structure of the conductive body 172c, and the common layer 360 around the sensing area SA can be separated from the common layer 360 of the surrounding display area DA. According to this, impurities such as moisture that can permeate around the opening HL of the substrate 110 in the sensing area SA may penetrate into the pixel circuit layer of the display area DA along the common layer 360, but the separation in the common layer 360 can prevent display defects due to corrosion or short-circuit defects.

Referring to FIG. 6 described above, the opening 410a may be formed by sequentially stacking and patterning the ninth insulating layer 410 and the twelfth insulating layer 450 on the substrate 110. The ninth insulating layer 410 may contact the upper surface and the side surface SE of the fifth conductive layer 172, and may contact the upper surface of the fifth insulating layer 162 positioned between the adjacent pads PD. Subsequently, the sixth conductive layer 460 may be formed by depositing and patterning a conductive material on the substrate 110. Unlike this, referring to FIG. 7 described above, after removing the protective pattern 210, the ninth insulating layer 410 and the twelfth insulating layer 450 are stacked on the substrate 110, and the ninth insulating layer 410 on the pad PD and the twelfth insulating layer 450 may also be removed, and then a conductive material may be laminated thereon and patterned to form the sixth conductive layer 460. Thereafter, the substrate 110 corresponding to the sensing area SA may be removed.

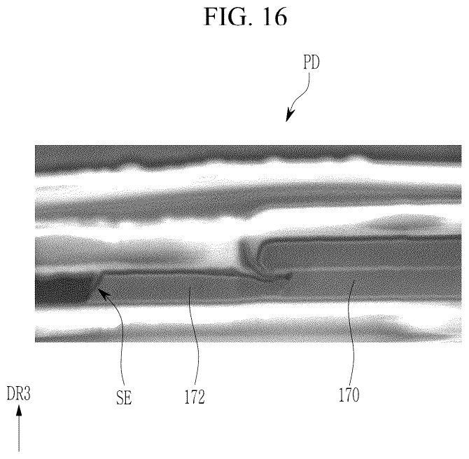

Referring to FIG. 16 to FIG. 21 together with the previously described drawings, the display device formed according to an embodiment will be compared with a comparative example.

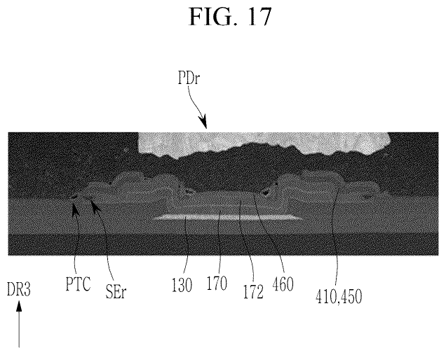

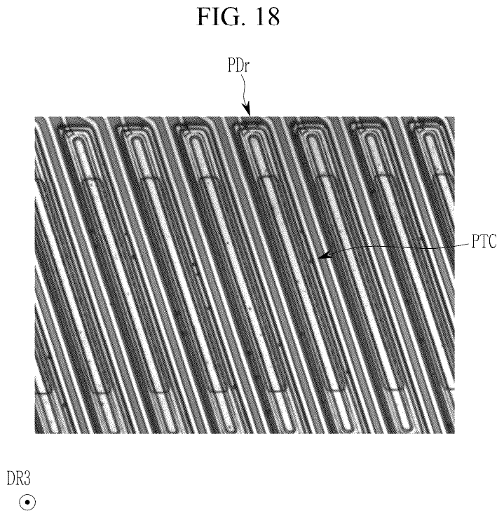

FIG. 16 shows a cross-sectional view of a pad of the display device according to an embodiment, FIG. 17 shows a cross-sectional view of a pad and its surroundings of the display device according to a comparative example, and FIG. 18 is a top plan photo of a pad area of the display device according to a comparative example.

Referring to FIG. 16, the side surface SE of the fifth conductive layer 172 of the pad PD of the display device formed according to the embodiment is covered and protected by the insulating pattern 180pp during the etching process for patterning the pixel electrodes of the display area, so metal is not precipitated, or the side surface SE get damaged on the side surface SE of the fifth conductive layer 172, which can generally have a smooth or flat surface, and the defect that the metal components of the fifth conductive layer 172 precipitate around the pad PD and remain in particle form can also be prevented.

Comparing FIG. 17 and FIG. 18 to FIG. 16, the pad PD of the display device according to the comparative example is almost the same as the pad PD of the display device according to the embodiment, but a pad PDr of FIG. 17 and FIG. 18 is not protected by pattern 180pp during the manufacturing process. Accordingly, the side surface SEr of the fifth conductive layer 172 of the pad PDr according to the comparative example is exposed to an etchant in an etching process for patterning the pixel electrode of the display area, so that metal components such as aluminum (Al) are precipitated, and the side surface SEr is rough (not flat or not smooth) and damaged, and the precipitated metal particles PTC remaining around the pad PDr may cause defects in a conductive layer or wiring to be formed in a subsequent process.

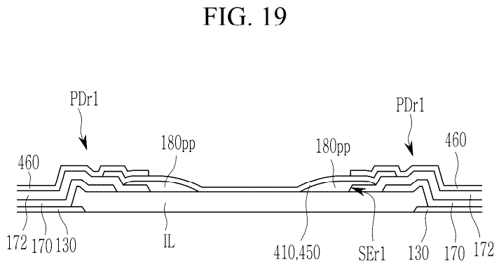

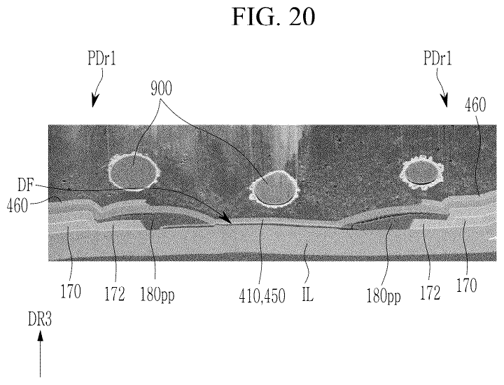

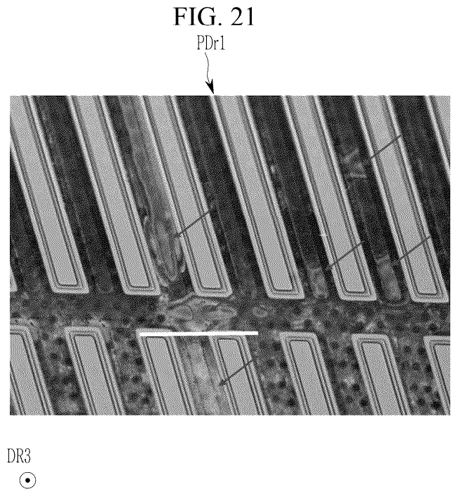

FIG. 19 is a cross-sectional view of a pad area of a display device according to a comparative example, FIG. 20 shows a cross-sectional view of a pad area of a display device according to a comparative example, and FIG. 21 is a top plan view of a pad area of a display device according to a comparative example.

Referring to FIG. 19, the manufacturing method and structure of the pad PDr1 of the display device according to one comparative example are substantially the same as the manufacturing method and structure of the pad PD of the display device according to the embodiment described above, but in the manufacturing process of the display device of FIG. 19, the insulating pattern 180pp in the middle of each pad PDr1 is not removed. Accordingly, in the manufacturing process of the display device according to the comparative example shown in FIG. 19, the side surface SEr1 of the fifth conductive layer 172 of the pad PDr1 is exposed to an etchant in an etching process for patterning the pixel electrode of the display area. Therefore, it may have a substantially smooth or flat surface similar to the side surface SE of the fifth conductive layer 172 of the pad PD of the display device of the present embodiment. However, referring to FIG. 20, when the pad PDr1 of the display device according to the comparative example is electrically connected to the driving unit, a conductive ball 900 may be positioned. During bonding and compression, as the conductive ball 900 presses the insulating pattern 180pp, the insulating pattern 180pp between the pads PDr1 may be lifted from the substrate 110 and the insulating layer thereon—for example, the ninth insulating layer 410 and the twelfth insulating layer 450 are also likely to have a defective portion DF that is lifted or peeled off. Accordingly, moisture may permeate between the adjacent pads PDr1, and thus short-circuit defects and corrosion between the adjacent pads PDr1 may easily occur.

Also, referring to FIG. 21, a Newton ring may be recognized around the pad PDr1 as indicated by the arrow, due to the bulging of the insulation pattern 180pp and/or the 9th insulating layer 410 and the twelfth insulating layer 450. However, according to the manufacturing method and structure of the display device according to the present embodiment, it is possible to prevent defects such as damage to the side of the fifth conductive layer 172 of the pad that can occur during the manufacturing process of the display device according to various comparative examples, and metal components being precipitated by the etching solution of the subsequent process, at the same time, since the insulating pattern 180pp that can cause the insulating layer to lift when the bonding pressure of the pad and the drive part is removed, it is also possible to prevent defects such as permeation, corrosion, and short-circuit caused by the lifting of the insulation layer.

Although the embodiments of the present invention have been described in detail above, the scope of the present invention is not limited thereto, and various modifications and improvements made by those skilled in the art using the basic concepts of the present invention defined in the following claims are also included in the scope of the present invention.

### DESCRIPTION OF SYMBOLS

72c: protruding part
110: substrate
112: barrier layer
116: buffer layer
120p, 126c, 126p: semiconductor layer
121: scan line
130, 130p: first conductive layer
136c, 138c, 170c, 172c: conductor
136p: second conductive layer
138p: third conductive layer
140, 142, 144, 160, 162, 164, 180, 350, 410, 410p, 420p, 430, 450, 450p, 470: insulating layer
142a, 162c, 215, 355, 410a: opening
170, 170p: fourth conductive layer
171: data line
172, 172p: fifth conductive layer
173: signal line
180pp: insulating pattern
210: protective pattern
210p: pixel electrode
270: common electrode
360: common layer
370: light emitting layer
380: encapsulation layer
460: sixth conductive layer
512, 522: sensing wire
520, 540: sensing electrode
521, 541: connection part
700: driving unit
900: conductive ball
1000: display panel

What is claimed is:

1. A display device, comprising:
a display area including a plurality of pixels; and
a pad area outside the display area and including a plurality of pads, wherein:
each of the pads includes
a first conductive layer on the substrate,
a second conductive layer on the first conductive layer,
a third conductive layer on the second conductive layer and covering a side surface of the second conductive layer, and
a fourth conductive layer on the third conductive layer;
the display area includes
a plurality of pixel electrodes,
a fifth conductive layer at the same layer as the third conductive layer on the substrate, and
a first insulating layer between the fifth conductive layer and the pixel electrode;
no insulating layer at the same layer as the first insulating layer exists between the third conductive layer and the fourth conductive layer of the pad; and
a side surface of the third conductive layer has a smooth surface.

2. The display device of claim 1, further comprising:
at least one insulating layer between the first conductive layer and the second conductive layer, wherein
the at least one insulating layer includes a first opening over the first conductive layer, and
the second conductive layer is electrically connected to the first conductive layer through the first opening.

3. The display device of claim 2, wherein:
a side surface of the third conductive layer contacts an uppermost surface of the at least one insulating layer.

4. The display device of claim 3, wherein:
an encapsulation layer is on the pixel electrode, and
further comprising a second insulating layer on the encapsulation layer,
the encapsulation layer includes at least one inorganic film and at least one organic film, and
the second insulating layer includes a portion in contact with the upper and side surfaces of the third conductive layer in the pad area.

5. The display device of claim 4, wherein:
the second insulating layer further includes a portion between two adjacent pads and contacting an uppermost surface of the at least one insulating layer.

6. The display device of claim 5, wherein:
the display area further includes a plurality of sensing electrodes on the pixel electrode; and
the fourth conductive layer of the pad is on the same layer as the sensing electrode and includes the same material.

7. The display device of claim 6, further comprising:
a third insulating layer between the second insulating layer and the fourth conductive layer, wherein
the fourth conductive layer is in contact with the upper surface of the third insulating layer, and
the second insulating layer and the third insulating layer include a second opening on the pad.

8. A method for manufacturing a display device, comprising:
forming a first conductive layer in a display area and a pad area of a substrate;
forming a second conductive layer in the display area and the pad area on the first conductive layer;
forming a third conductive layer in the display area and the pad area on the second conductive layer;
forming a first insulating layer in the display area and the pad area on the third conductive layer;
forming a plurality of pixel electrodes in the display area on the first insulating layer;
forming a protective pattern on the third conductive layer after forming the plurality of pixel electrodes; and
removing the first insulating layer in the pad area using the protective pattern as a mask, wherein
the first insulating layer includes an organic insulating material, and
the first insulating layer in the pad area before being removed covers a side surface of the third conductive layer in the pad area.

9. The method for manufacturing a display device of claim 8, wherein:
regions of the first conductive layer, the second conductive layer, and the third conductive layer in the pad area are sequentially stacked on the substrate and are electrically connected to each other to form a plurality of pads; and
a region between adjacent pads does not contain the first insulating layer.

10. The method for manufacturing a display device of claim 9, wherein after the step of removing the first insulating layer in the pad area, the method further comprises:
removing the protective pattern; and
forming a fourth conductive layer on the display area and the pad area on the third conductive layer,
regions of the fourth conductive layer in the pad area being electrically connected to respective regions of the third conductive layer in the pad area and being respectively included in the pads.

11. The method for manufacturing a display device of claim 10, further comprising:
forming at least one insulating layer in the display area and the pad area after forming the first conductive layer and before forming the second conductive layer,
the at least one insulating layer including a first opening over the first conductive layer in the pad area, and
the second conductive layer of the pad area being electrically connected to the first conductive layer of the pad area through the first opening.

12. The method for manufacturing a display device of claim 11, wherein:
a side surface of the third conductive layer contacts an uppermost surface of the at least one insulating layer.

13. The method for manufacturing the display device of claim 12, further comprising:
forming an encapsulation layer including at least one inorganic film and at least one organic film on the pixel electrode, and
forming a second insulating layer on the encapsulation layer,
the second insulating layer including a portion in contact with upper and side surfaces of the third conductive layer in the pad area.

14. The method for manufacturing a display device of claim 13, wherein:
a portion of the second insulating layer is between the third conductive layers adjacent to the pad area and contacting an uppermost surface of the at least one insulating layer.

15. The method for manufacturing a display device of claim 14, wherein:
the fourth conductive layer is formed after forming the encapsulation layer, and
the fourth conductive layer in the display area includes a plurality of sensing electrodes.

16. The method for manufacturing a display device of claim 15, further comprising:
forming a third insulating layer in the display area and the pad area after forming the second insulating layer and before forming the fourth conductive layer;
the fourth conductive layer being in contact with the upper surface of the third insulating layer, and
the second insulating layer and the third insulating layer including a second opening on the pad.

17. The method for manufacturing a display device of claim 8, wherein:
the display area includes a sensing area,
removal of the first insulating layer includes removing the first insulating layer around the sensing region, and
further comprising the step of removing a portion of the substrate in the sensing area.

18. The method for manufacturing a display device of claim 8, further comprising:
after forming the plurality of pixel electrodes, further comprising forming a fourth insulating layer on the pixel electrodes,
the fourth insulating layer having an opening over the pixel electrodes, and
the protective pattern being formed after forming the fourth insulating layer.

19. The method for manufacturing a display device of claim 8, wherein:
the protective pattern includes a metal oxide including IGZO.

20. The method for manufacturing a display device of claim 8, further comprising:
removing the protective pattern after removing the first insulating layer.
